(19) United States
(12) Patent Application Publication
(10) Pub. No.: US 2024/0146018 A1
(43) Pub. Date: May 2, 2024

(54) OPTICAL COMMUNICATION MODULE AND METHOD FOR MANUFACTURING THE SAME

(71) Applicant: Mitsubishi Electric Corporation, Tokyo (JP)

(72) Inventor: Nao HIROSHIGE, Tokyo (JP)

(73) Assignee: Mitsubishi Electric Corporation, Tokyo (JP)

(21) Appl. No.: 18/264,590

(22) PCT Filed: Feb. 16, 2021
(86) PCT No.: PCT/JP2021/005605

§ 371 Date: Aug. 8, 2023

(51) Int. Cl. H01S 5/0232; H01S 5/0231; H01S 5/0237; H01S 5/024

(52) U.S. Cl. CPC H01S 5/0232; H01S 5/0231; H01S 5/0237; H01S 5/02469

(57) ABSTRACT

An optical communication module of the present disclosure includes a plate-shaped stem, a plurality of leads penetrating through the stem via an insulating member, a conductive member for connection formed on either a top surface or a side surface of at least one lead among the plurality of leads, a heat sink block provided on the stem, a sub-mount which is fixed to the heat sink block and is provided with a metal pattern on a flat surface thereof, a semiconductor light emitting element which is fixed to the metal pattern and emits laser light, and a wire in which a metal ball formed at one end thereof is bonded to the metal pattern and the other end thereof is bonded to the at least one lead through bonding to the conductive member for connection.

### TECHNICAL FIELD

The present application relates to an optical communication module and a method for manufacturing the same.

### BACKGROUND ART

In recent years, the amount of data transmission in mobile communication systems has been rapidly increasing, and with the introduction of the fifth generation mobile communication system (5G) and its spread after the introduction, a further enormous amount of transmission is expected.

In order to process an enormous amount of data communication at high speed, high-speed operation of an optical communication module used in a communication apparatus is essential. Further, in order to make the communication apparatus compact, it is also important to make the optical communication module compact.

As a light source used for the optical communication module, a form in which a semiconductor light emitting element represented by a semiconductor laser which emits laser light is incorporated into a so-called CAN package is common. Consequently, it is indispensable to develop a technique for further increasing the speed of the frequency response characteristic of the CAN package itself and downsizing the entire CAN package while maintaining the high-frequency response characteristic.

For example, Patent Document 1 discloses a semiconductor light emitting element incorporated in a package. In the semiconductor light emitting element shown in FIG. 1 of Patent Document 1, wires are provided to electrically connect a plurality of leads and the semiconductor light emitting element bonded with solder or the like to a sub-mount fixed to a flat surface of a heat sink of a stem provided with the plurality of leads.

### CITATION LIST

### Patent Document

Patent Document 1: Japanese Laid-Open Patent Publication No. 2005-26333

### SUMMARY OF THE INVENTION

### Problems to be Solved by the Invention

The wire of the semiconductor light emitting element disclosed in FIG. 1 of Patent Document 1 stands substantially vertically from the surface to which the wires are bonded. This is because when wire bonding is performed to form the wires between the semiconductor light emitting element and the leads, a capillary supporting the wire is lowered from a vertical direction with respect to the surface to which the wires are bonded.

Consequently, the wires for electrically connecting an electrode on an upper portion of the semiconductor light emitting element and the leads must have largely bent loop shapes, but such a wire length having a large redundancy causes a large inductance when the semiconductor light emitting element is driven, which hinders improvement of high-frequency characteristics.

Further, at the time of wire bonding, one end of the wire is generally ball-bonded and the other end is stitch-bonded, but when the wire length is intended to be shortened, the tensile strength applied to the bonding surface of the wire increases, so that it is necessary to increase the bonding strength of the wire particularly on the stitch-bonded side.

The present disclosure discloses a technique for solving the problem as described above, and provides an optical communication module having excellent high-frequency characteristics and a method for manufacturing the same.

### Solution to the Problems

An optical communication module according to the present disclosure includes: a plate-shaped stem; a plurality of leads penetrating through the stem via insulating members; a conductive member for connection formed on either a top surface or a side surface of at least one lead among the plurality of leads; a heat sink block provided on the stem; a sub-mount which is fixed to the heat sink block and is provided with a metal pattern on a flat surface thereof; a semiconductor light emitting element which is fixed to the metal pattern and emits laser light; and a wire in which a metal ball formed at one end thereof is bonded to the metal pattern and the other end thereof is bonded to the at least one lead through bonding to the conductive member for connection.

A method for manufacturing an optical communication module according to the present disclosure includes: fixing a sub-mount having a metal pattern formed on a flat surface thereof to a heat sink block provided on a plate-shaped stem; fixing a semiconductor light emitting element to the metal pattern; bonding a metal ball formed at one end of a wire to the metal pattern in a state where a flat surface of the stem is inclined at an angle of 90°−θₜ with respect to a reference surface, the reference surface being a surface perpendicular to an axial direction of a capillary, the capillary having a tapered shape expanding at a taper angle et from a tip end thereof and supporting the wire by a wire insertion hole provided along a central axis; forming a conductive member for connection on either a top surface or a side surface of at least one lead among a plurality of leads provided so as to penetrate through the stem; and bonding the other end of the wire to the at least one lead through bonding to the conductive member for connection in a state in which the flat surface of the stem is inclined at the taper angle θₜ with respect to the reference surface.

### Effect of the Invention

According to the optical communication module disclosed in the present application, since the wire length can be shortened and the bonding strength is strong, thus providing an effect of obtaining an optical communication module having excellent high-frequency characteristics.

According to the method for manufacturing an optical communication module disclosed in the present application, since it is possible to form a wire having a short wire length with strong bonding strength, thus providing an effect that an optical communication module having excellent high-frequency characteristics can be easily manufactured.

### BRIEF DESCRIPTION OF THE DRAWINGS

FIG. 1 is a schematic view of an optical communication module according to Embodiment 1.

FIG. 2 is an enlarged schematic view of a main part of the optical communication module according to Embodiment 1.

FIG. 3 is an enlarged schematic view of a main part of the optical communication module according to Embodiment 1.

FIG. 4 is a schematic view showing a method for manufacturing an optical communication module according to Embodiment 1.

FIG. 5 is an enlarged schematic view of a main part of an optical communication module according to Modification 1 of Embodiment 1.

FIG. 6 is a schematic diagram showing a positional relationship between a lead and a sub-mount in an optical communication module according to Modification 2 of Embodiment 1.

FIG. 7 is an enlarged schematic view of a main part of the optical communication module according to Embodiment 2.

FIG. 8 is an enlarged schematic view of a main part of an optical communication module according to Embodiment 3.

FIG. 9 is a schematic view showing a main part of an optical communication module according to Embodiment 4.

FIG. 10 is a schematic view showing a method for manufacturing an optical communication module according to Embodiment 4.

FIG. 11 is a schematic view showing a method for manufacturing an optical communication module according to Embodiment 5.

FIG. 12 is a schematic view showing a method for manufacturing an optical communication module according to Embodiment 6.

FIG. 13 is a schematic view showing a main part of an optical communication module and a method for manufacturing an optical communication module according to Embodiment 7.

FIG. 14 is a schematic view showing a method for manufacturing an optical communication module according to Embodiment 8.

FIG. 15 is a schematic view showing a method for manufacturing an optical communication module according to Embodiment 9.

FIG. 16 is a schematic view showing a method for manufacturing an optical communication module according to Embodiment 10.

FIG. 17 is a schematic view showing a method for manufacturing an optical communication module according to Embodiment 11.

FIG. 18 is an enlarged schematic view of a main part of an optical communication module according to Embodiment 12.

### DESCRIPTION OF EMBODIMENTS

### Embodiment 1

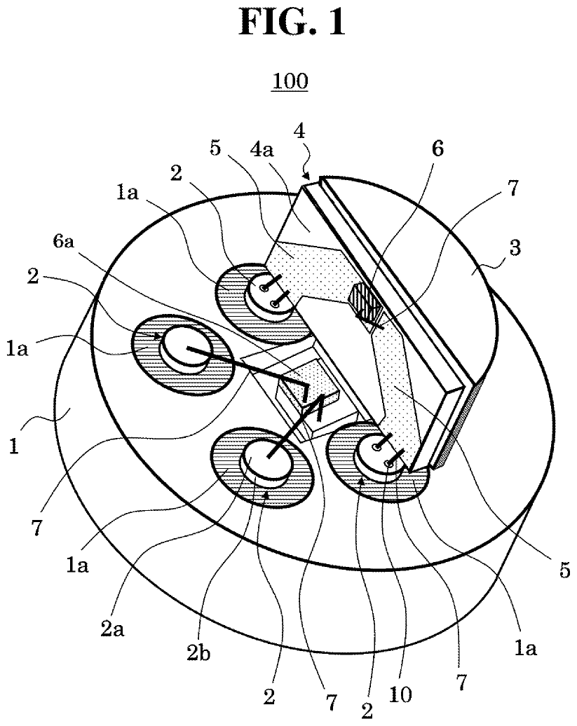

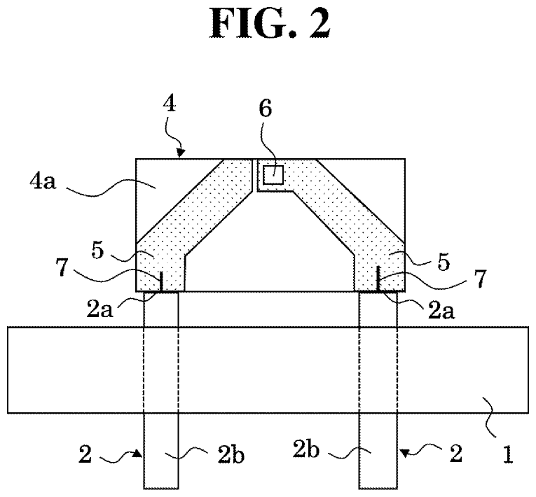

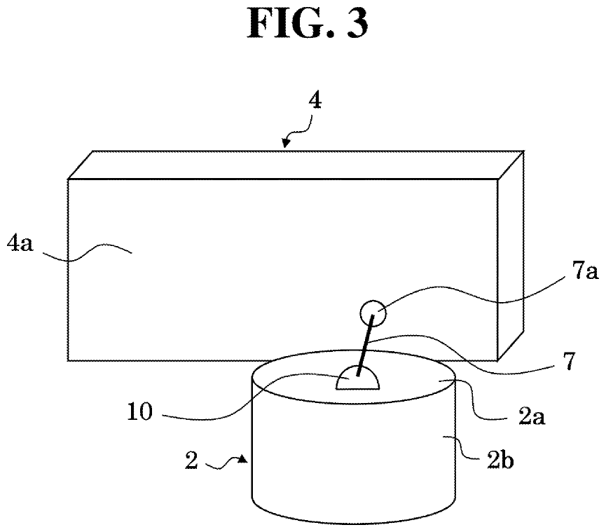

FIG. 1 is a schematic view of an optical communication module according to Embodiment 1. FIG. 2 and FIG. 3 are enlarged schematic views of a main part of the optical communication module according to Embodiment 1.

An optical communication module 100 includes a plate-shaped stem 1, a plurality of leads 2 provided so as to penetrate the stem 1, a heat sink block 3 arranged on a flat surface of the stem 1, a sub-mount 4 which is fixed with solder to a surface of the heat sink block 3 perpendicular to the flat surface of the stem 1, a semiconductor light emitting element 6 which is fixed with solder to a metal pattern 5 provided on a side of a flat surface 4a of the sub-mount 4 (hereinafter referred to as sub-mount flat surface 4a) opposed to the surface fixed to the heat sink block 3, a wire 7 whose one end is bonded to the metal pattern 5 formed on the sub-mount flat surface 4a and whose the other end is bonded to the lead 2 through bonding to a conductive member for connection 10 formed on a top surface 2a of the lead or a side surface 2b of the lead.

The stem 1 and the lead 2 are electrically insulated from each other by an insulating member 1a provided between the stem 1 and the lead 2. An example of the insulating member 1a is a glass-like insulating material. That is, the lead 2 penetrates through the stem 1 via the insulating member 1a.

A semiconductor light receiving element 6a is mounted on the stem 1 at a position opposite to the laser emission end surface of the semiconductor light emitting element 6. The semiconductor light receiving element 6a functions to monitor the laser light emitted from the semiconductor light emitting element 6 by receiving the laser light emitted from the rear surface side of the semiconductor light emitting element 6 and converting it into an electric signal.

FIG. 2 is a schematic view showing a main part including the stem 1, the lead 2, and the sub-mount 4 in the optical communication module according to Embodiment 1.

The conductive member for connection 10 (not shown) formed on the top surface 2a of the lead 2 provided so as to penetrate through the plate-shaped stem 1 and the metal pattern 5 formed on the sub-mount flat surface 4a perpendicular to the flat surface of the plate-shaped stem 1 are electrically connected with the wire 7. That is, one end of the wire 7 is bonded to the metal pattern 5 formed on the sub-mount flat surface 4a, and the other end of the wire 7 is bonded to the lead 2 through the bonding to the conductive member for connection 10 formed on the top surface 2a of the lead.

A semiconductor light emitting element 6 is fixed to the metal pattern 5 with solder.

Each of the plurality of leads 2 is electrically connected to a predetermined portion of the metal pattern 5 through the separate wire 7.

FIG. 3 is an enlarged schematic view of a main part including the wire 7 of the optical communication module according to Embodiment 1. The metal ball 7a is formed at one end of the wire 7 on the sub-mount 4 side, and the wire 7 is bonded to the metal pattern 5 (not shown) formed on the sub-mount flat surface 4a through the metal ball 7a.

As described above, the conductive member for connection 10 is formed on the top surface 2a of the lead. An example of the conductive member for connection 10 is a bump. However, the conductive member for connection 10 is not limited to the bump but may be a member having high conductivity and excellent adhesion to the wire 7.

The other end of the wire 7 is bonded to the lead 2 through the bonding to the conductive member for connection 10 formed on the top surface 2a of the lead. The wire 7 functions as a current path between the metal pattern 5 and the lead 2. The length of the wire 7, that is, the wire length is preferably as short as possible from the viewpoint of high-frequency characteristics, but the wire should not come into contact with the stem 1 or the like.

Noted that FIG. 3 shows an example in which the conductive member for connection 10 is formed on the top surface 2a of the lead. The conductive member for connection 10 may be formed on the side surface 2b of the lead and bonded to the wire 7.

In the optical communication module according to Embodiment 1, since the other end of the wire 7 is bonded so as to be electrically connected to the lead 2 through the bonding to the conductive member for connection 10, the bonding strength between the other end of the wire 7 and the lead 2 is remarkably increased as compared with the case where the other end of the wire 7 is bonded to the lead 2 simply by stitch bonding. Therefore, it is possible to achieve stable wire connection with high tolerance to an increase in tensile strength of the wire 7 caused by shortening the wire length of the wire 7, thus providing an effect of obtaining an optical communication module having excellent high-frequency characteristics.

The operation of the optical communication module according to Embodiment 1 will be described below.

When a positive voltage is applied to one of the plurality of leads 2 and a negative voltage is applied to another one of the plurality of leads 2 by an external power supply (not shown) to apply a voltage in a forward bias direction to the PN junction inside the semiconductor light emitting element 6, a current flows through the semiconductor light emitting element 6, laser oscillation generates, and the laser light is emitted from the emission end surface of the semiconductor light emitting element 6 to the outside. The laser light emitted from the end surface opposite to the emission end surface is received by the semiconductor light receiving element 6a mounted on the stem 1, converted into an electric signal, and used as a monitor output of the laser light.

Next, a method for manufacturing an optical communication module according to Embodiment 1 will be described below.

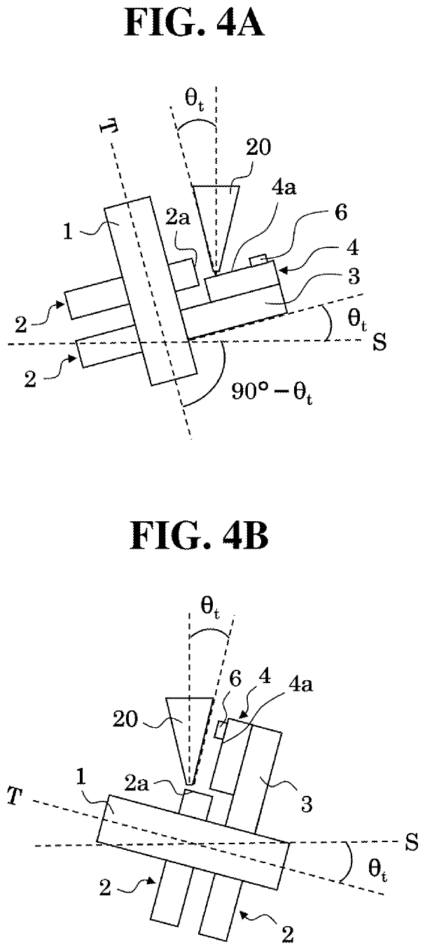

FIG. 4 is a schematic diagram for explaining a wire bonding method of the wire 7 which is characteristic in the manufacturing method for an optical communication module according to Embodiment 1.

The sub-mount 4 is fixed with solder to a flat surface perpendicular to the flat portion of the stem 1 in the heat sink block 3 provided on the stem 1. Noted that the stem 1 and the heat sink block 3 are integrated.

The metal pattern 5 is provided in advance on the sub-mount flat surface 4a of the fixed sub-mount 4. The semiconductor light emitting element 6 is fixed to a predetermined position of the metal pattern 5 with solder. A back surface electrode (not shown) is formed on the back surface side of the semiconductor light emitting element 6. The metal pattern 5 and the back surface electrode provided on the back surface side of the semiconductor light emitting element 6 are fixed to each other, whereby the metal pattern 5 and the semiconductor light emitting element 6 are electrically connected to each other and a current can be supplied to the semiconductor light emitting element 6.

The metal ball 7a is formed by dropping a wire material from a tip end of a nozzle-type capillary 20 of a wire bonding apparatus (not shown) and melting the tip end of the wire material by electric discharge from a torch electrode (not shown). Gold is generally used as the wire material, but a conductive material other than gold may be used.

A ball bonding method in the manufacturing method for the optical communication module according to Embodiment 1 is shown in FIG. 4A.

The nozzle-type capillary 20 shown in FIG. 4A has a shape spreading from a tip end of the capillary 20, that is, a tapered shape. A wire insertion hole (not shown) in the center of the capillary 20 introduces and supports the wire material. The wire material is supplied from the back side of the capillary 20 as needed. An angle between a tapered surface and a central axis of the capillary 20 is referred to as a taper angle θₜ of the capillary 20. Hereinafter, a direction formed by the central axis of the capillary 20 is referred to as an axial direction of the capillary 20.

The capillary 20 is lowered in a direction in which the optical communication module is placed by a capillary vertical moving mechanism (not shown) of the wire bonding apparatus. The metal ball 7a provided at the tip end of the wire material, that is, the metal ball 7a formed at one end of the wire 7 is pressed against the metal pattern 5 formed on the sub-mount flat surface 4a, and the metal ball 7a is bonded to the metal pattern 5 by thermocompression bonding while applying ultrasonic vibration. Such a wire bonding method is called ball bonding.

At the time of the ball bonding to the sub-mount flat surface 4a, as shown in FIG. 4A, the axial direction of the capillary 20 is inclined by the taper angle θₜ in the direction away from the flat portion of the stem 1 with respect to the direction perpendicular to the sub-mount flat surface 4a. Assuming that a plane perpendicular to the axial direction of the capillary 20 is a reference plane S, a plane T parallel to the flat portion of the stem 1 is inclined to the capillary 20 side at an angle of 90°−θₜ with respect to the reference plane S.

As described above, the ball bonding is performed on the metal pattern 5 in a state where the stem 1 is inclined with respect to the capillary 20. This means that when viewed from the side of the sub-mount flat surface 4a, the capillary 20 is lowered from a direction inclined by the taper angle θₜ with respect to the direction perpendicular to the sub-mount flat surface 4a, and the metal ball 7a formed at one end of the wire 7 is bonded to the metal pattern 5 by thermocompression bonding.

Next, as shown in FIG. 4B, the other end of the wire 7 is pressed against the conductive member for connection 10 (not shown) on the top surface 2a of the lead 2 by thermocompression bonding to be bonded to the lead 2 through the bonding to the conductive member for connection 10.

At the time of stitch bonding, the stem 1 is rotated from the position at the time of performing the above-described ball bonding such that the angle between the plane T parallel to the flat portion of the stem 1 and the reference plane S is inclined by the angle of the taper angle θₜ, and then fixed. While maintaining this state, the capillary 20 is lowered to the side of the top surface 2a of the lead by the capillary vertical moving mechanism (not shown), and the other end of the wire 7 is stitch-bonded to the conductive member for connection 10 on the top surface 2a of the lead. That is, the other end of the wire 7 is bonded to the lead 2 through bonding to the conductive member for connection 10.

A surface electrode (not shown) is formed on the upper surface side of the semiconductor light emitting element 6, and wire bonding is performed between the surface electrode and a predetermined position of the metal pattern 5 by another wire 7 (not shown).

The bump as an example of the conductive member for connection 10 formed on the top surface 2a of the lead can be easily formed at the tip end of a wire material by dropping the wire material from a tip end of the capillary 20 above the top surface 2a of the lead and melting the tip end of the wire material by electric discharge from a torch electrode, lowering the capillary 20 to the top surface 2a of the lead, pressing the metal ball against the top surface 2a of the lead by thermocompression bonding, raising the capillary 20 while leaving the metal ball on the top surface 2a of the lead, and cutting the remaining wire material so as to leave only the metal ball in a clamped state of the wire material. Gold is an example of a metal constituting the bump.

According to the wire bonding method with the wire 7 between the metal pattern 5 formed on the sub-mount flat surface 4a and the top surface 2a of the lead through the conductive member for connection 10, which is characteristic of the manufacturing method for the optical communication module according to Embodiment 1 described above, the following effects can be obtained.

In the conventional wire bonding method in the optical communication module, the wire bonding with the wire 7 between the metal pattern 5 and the lead 2 is performed by lowering the capillary 20 from the vertical direction with respect to the sub-mount flat surface 4a, ball bonding one end of the wire 7 to the metal pattern 5 formed on the sub-mount flat surface 4a, then rotating the stem 1 by 90°, lowering the capillary 20 from the vertical direction with respect to the top surface 2a of the lead, and stitch bonding the other end of the wire 7 to the top surface 2a of the lead.

In such a conventional wire bonding method, in order to shorten the wire length of the wire 7 for the purpose of improving the high-frequency characteristics of the optical communication module, it is necessary to perform ball bonding at a portion as close to the lead 2 as possible in the metal pattern 5 formed on the sub-mount flat surface 4a.

However, if an attempt is made to perform the ball bonding on a portion of the metal pattern 5 that is too close to the lead 2, when the capillary 20 that expands in a tapered shape from the tip end thereof is lowered toward the metal pattern 5, there arises a problem that the tapered side surface of the capillary 20 comes into contact with the stem 1 or a part of the lead 2 that stands up from the stem 1. Consequently, it is necessary to perform wire bonding on a portion of the metal pattern 5 which is at a certain distance from the stem 1 or the lead 2.

In the connection between the other end of the wire 7 and the lead 2, if the lead 2 and the sub-mount 4 are too close to each other, when the other end of the wire 7 is stitch-bonded to the top surface 2a of the lead, there is a possibility that the tapered side surface of the capillary 20 comes into contact with the sub-mount flat surface 4a while the capillary 20 extending in the tapered shape from the tip end thereof is lowered toward the top surface 2a of the lead.

Consequently, in the conventional wire bonding method, it is necessary to set the distance between the lead 2 and the wire bonding position on the metal pattern 5 formed on the sub-mount flat surface 4a to such an extent that the above-mentioned problem does not occur. That is, when the wire length is shortened for the purpose of improving the high-frequency characteristics, there is a limitation in the manufacturing method that shortening of the wire length is limited due to the tapered shape of the capillary 20.

In the method for manufacturing an optical communication module according to Embodiment 1, the above-described wire bonding method is applied in order to break the restriction on the shortening of the wire length by the conventional technique.

That is, when the manufacturing method for the optical communication module according to Embodiment 1 is applied, since the stem 1 is rotated from the reference plane S to the position shown in FIG. 4A or FIG. 4B in accordance with the taper angle θₜ of the capillary 20, contact between the capillary 20 and the stem 1 or the sub-mount 4 can be avoided even if the ball bonding is performed at a position closer to the lead 2 on the metal pattern 5 formed on the sub-mount flat surface 4a.

The effects of the method for manufacturing an optical communication module according to Embodiment 1 will be described in detail below.

As shown in FIG. 4A, since the capillary 20 is inclined by the taper angle θₜ in the direction away from the stem 1 or the lead 2 with respect to the sub-mount flat surface 4a, the distance between the tapered side surface of the capillary 20 and the stem 1 or the lead 2 is larger than that in the case where the capillary 20 is lowered from the direction perpendicular to the sub-mount flat surface 4a, whereby the capillary 20 can be lowered to a portion closer to the stem 1 or the lead 2 on the sub-mount 4. That is, when the wire 7 is ball-bonded to the sub-mount 4, mechanical interference between the stem 1 or the lead 2 and the capillary 20 can be avoided.

When the capillary 20 is lowered toward the top surface 2a of the lead, the same effect as described above can be obtained by inclining the stem 1 as shown in FIG. 4B. That is, when the wire 7 is stitch-bonded to the lead 2, mechanical interference between the sub-mount 4 and the capillary 20 can be avoided.

That is, according to the above-described wire bonding method, the interference between the capillary 20 and each member on the optical communication module side can be further reduced, thus providing an effect that the wire length shorter than that in the related art can be realized.

The wire bonding method in which the stem 1 is rotated corresponding to the taper angle θₜ in the connection of the wire 7 has been described in detail above. In the method for manufacturing an optical communication module according to Embodiment 1, the following structure and manufacturing method are applied in order to ensure the connection of the wire 7.

In the above-described wire bonding method, the surface to be wire-bonded is inclined by the taper angle θₜ with respect to the descending direction of the capillary 20. In the case of ball bonding, since the metal ball 7a formed at the tip end of the wire 7 is pressed against the metal pattern 5 by thermocompression bonding, even if the wire bonding is performed in the direction inclined at the taper angle θₜ, the bonding strength of the wire 7 is about the same as that of the conventional wire bonding performed in the vertical direction, so that no problem arises with respect to the bonding strength of the wire 7.

On the other hand, in the stitch bonding to the top surface 2a of the lead, since the top surface 2a of the lead to be stitch-bonded is inclined at the taper angle θₜ with respect to the descending direction of the capillary 20, the bonding strength of the wire 7 tends to be remarkably reduced as compared with the stitch bonding from the vertical direction.

Consequently, in the method for manufacturing an optical communication module according to Embodiment 1, since the conductive member for connection 10 such as the bump is formed in advance on the top surface 2a of the lead and the other end of the wire 7 is bonded to the conductive member for connection 10 by thermocompression bonding, even when the descending direction of the capillary 20 is inclined with respect to the top surface 2a of the lead, it is possible to stably realize strong bonding strength between the wire 7 and the lead 2.

Although the rotation angle of the stem 1 is determined in accordance with the taper angle θₜ of the capillary 20 in the above description, it is needless to say that an effect corresponding to each angle can be obtained even if the stem 1 is inclined at an angle smaller or larger than the taper angle θₜ of the capillary 20.

As described above, in the optical communication module according to Embodiment 1, the wire length of the wire 7 between the lead 2 and the metal pattern 5 formed on the sub-mount flat surface 4a can be shortened, and the wire 7 having the strong bonding strength is provided even when the wire length is shortened, thus providing an effect that an optical communication module capable of realizing excellent high-frequency characteristics can be obtained.

Further, in the method for manufacturing an optical communication module according to Embodiment 1, since the wire bonding is performed by inclining the stem 1 corresponding to the taper angle θₜ of the capillary 20 of the wire bonding apparatus, it is possible to easily form the wire 7 having a shorter wire length, thus providing an effect that an optical communication module having excellent high-frequency characteristics can be easily manufactured.

### Modification 1 of Embodiment 1

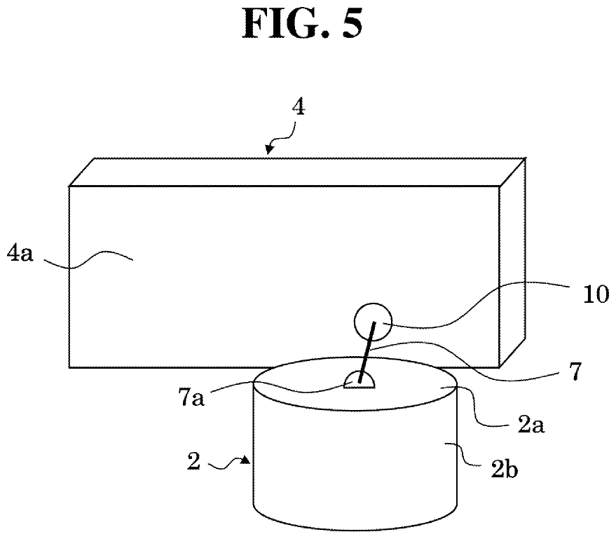

FIG. 5 is an enlarged schematic view of a main part including the wire 7 of the optical communication module according to Modification 1 of Embodiment 1.

In the optical communication module according to Embodiment 1, the conductive member for connection 10 is formed on the lead 2 side, and the lead 2 and the metal pattern 5 formed on the sub-mount flat surface 4a are connected to each other with the wire 7. In the optical communication module according to Modification 1 of Embodiment 1, the arrangement of the conductive member for connection 10 is reversed with respect to the optical communication module according to Embodiment 1. That is, in the optical communication module according to Modification 1 of Embodiment 1, the bump which is an example of the conductive member for connection 10 is formed on the metal pattern 5 (not shown) formed on the sub-mount flat surface 4a.

A method for manufacturing an optical communication module according to Modification 1 of Embodiment 1 differs from the method for manufacturing an optical communication module according to Embodiment 1 in the following points.

In the wire bonding for providing the wire 7, the wire bonding between the lead 2 and the metal pattern 5 is realized by pressing the metal ball 7a provided at one end of the wire 7 against the top surface 2a of the lead by thermocompression bonding and bonding the other end of the wire 7 to the conductive member for connection 10 formed on the metal pattern 5 on the sub-mount flat surface 4a by stitch bonding.

Noted that one end of the wire 7 is ball-bonded to the top surface 2a of the lead. In this case, since the bonding strength of the wire 7 between the wire 7 and the lead 2 is sufficiently strong, stable wire connection can be maintained even when the wire length is shortened.

In the optical communication module according to Modification 1 of Embodiment 1, since the other end of the wire 7 is electrically connected to the metal pattern 5 formed on the sub-mount flat surface 4a through the bonding to the conductive member for connection 10, the bonding strength between the other end of the wire 7 and the metal pattern 5 is remarkably increased as compared with the case of thermocompression bonding the other end of the wire 7 and the metal pattern 5 simply by stitch bonding. Therefore, wire bonding having stable bonding strength with high tolerance against increase in tensile strength of the wire caused by shortening of the wire length can be achieved, thus providing an effect that an optical communication module having excellent high-frequency characteristics can be obtained.

### Modification 2 of Embodiment 1

In the optical communication module according to Embodiment 1, for example, as shown in FIG. 3, the top surface 2a of the lead and the sub-mount flat surface 4a are perpendicular to each other. On the other hand, in the optical communication module according to Modification 2 of Embodiment 1, the top surface 2a of the lead and the sub-mount flat surface 4a are not perpendicular to each other but form an acute angle or an obtuse angle.

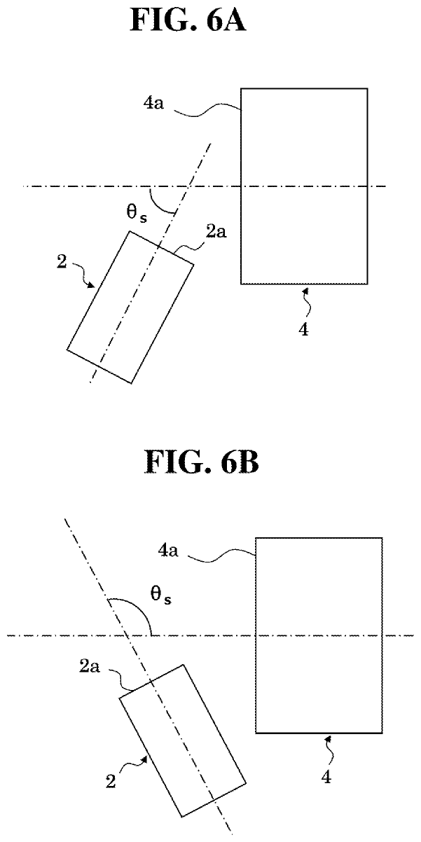

FIG. 6 is a schematic diagram showing a positional relationship between the lead 2 and the sub-mount 4 in the optical communication module according to Modification 2 of Embodiment 1. FIG. 6A schematically shows a case where an angle θₛ formed by the top surface 2a of the lead and the sub-mount flat surface 4a is an acute angle, and FIG. 6B schematically shows a case where the angle θs formed by the top surface 2a of the lead and the sub-mount flat surface 4a is an obtuse angle. Noted that, constituent elements other than the lead 2 and the sub-mount 4 are omitted in FIG. 6.

Even in the positional relationship between the lead 2 and the sub-mount 4 as described above, the lead 2 and the sub-mount 4 in the positional relationship as described above can be stably connected to each other with the strong bonding strength with the wire 7 using the wire bonding method described in the manufacturing method for the optical communication module according to Embodiment 1 or Modification of Embodiment 1. Such a wire bonding method can be effectively applied when the angle θₛ formed by the top surface 2a of the lead and the sub-mount flat surface 4a is larger than 0° and smaller than 180°.

As described above, in the optical communication module according to Modification 2 of Embodiment 1, even when the positional relationship between the lead 2 and the sub-mount 4 is not perpendicular to each other, that is, even when the angle θₛ formed by the top surface 2a of the lead and the sub-mount flat surface 4a is larger than 0° and smaller than 180°, it is possible to provide the wire 7 having the strong bonding strength in shortening the wire length, thus providing an effect that the flexibility of the arrangement place of the lead 2 inside the optical communication module is enhanced and an optical communication module having excellent high-frequency characteristics can be obtained.

### Embodiment 2

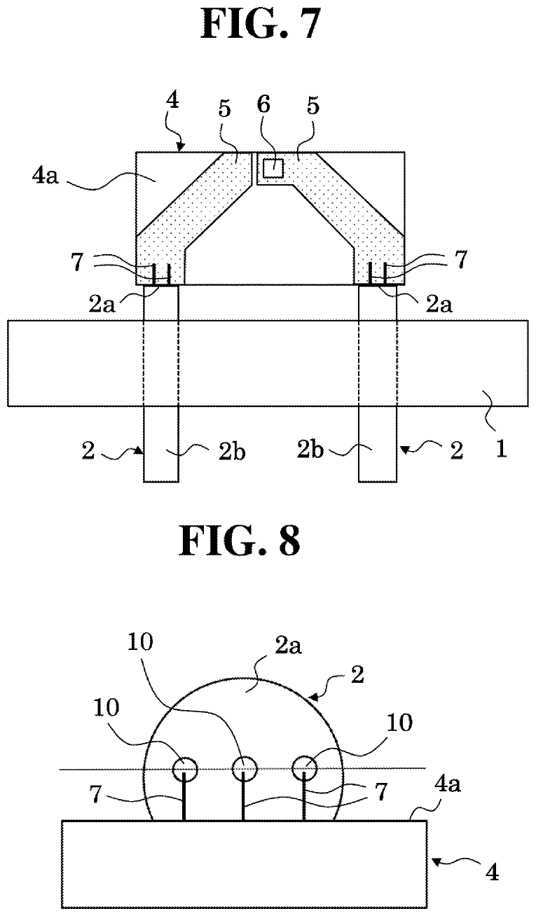

FIG. 7 is a schematic view showing a main part including the stem 1, the lead 2, and the sub-mount 4 in the optical communication module according to Embodiment 2.

The optical communication module according to Embodiment 2 has two or more wires 7, that is, a plurality of wires for electrically connecting the top surface 2a of one lead 2 and the metal pattern 5 formed on the sub-mount flat surface 4a.

A plurality of conductive members for connection 10 (bumps, not shown) are formed on the top surface 2a of one lead 2, and the other end of each wire 7 is thermocompression-bonded to the conductive member for connection 10 by stitch bonding, whereby the plurality of wires 7 are provided between the lead 2 and the metal pattern 5 formed on the sub-mount flat surface 4a. The wire bonding method is the same as that of Embodiment 1.

As shown in FIG. 7, by forming two or more wires 7 for electrically connecting one lead 2 and the metal pattern 5, it is possible to eliminate deterioration of high-frequency characteristics which is a problem when the lead 2 and the metal pattern 5 are connected with the wire 7.

As described above, in the optical communication module according to Embodiment 2, since the plurality of wires 7 are provided between the lead 2 and the metal pattern 5 formed on the sub-mount flat surface 4a, thus providing an effect of obtaining an optical communication module capable of realizing more excellent high-frequency characteristics than the case where the lead 2 and the metal pattern 5 are connected by one wire 7.

### Embodiment 3

FIG. 8 is a schematic view showing a main part including the lead 2 and the sub-mount 4 in the optical communication module according to Embodiment 3.

In the optical communication module according to Embodiment 3, as shown in FIG. 8, a plurality of wires 7 are bonded to the top surface 2a of one lead through the conductive members for connection 10 so as to be arranged in a row along a direction parallel to the sub-mount flat surface 4a perpendicular to the top surface 2a of the one lead 2. Noted that FIG. 8 also shows the arrangement of the conductive members for connection 10 to which the other ends of the wires 7 are connected.

On the top surface 2a of the lead 2, the plurality of conductive members for connection 10 (bumps) are formed so as to be arranged in a row along the direction parallel to the sub-mount flat surface 4a perpendicular to the top surface 2a of the lead 2. The other end of each wire 7 is thermocompression-bonded to each conductive member for connection 10 by stitch bonding, whereby the plurality of wires 7 are provided between the lead 2 and the metal pattern 5 formed on the sub-mount flat surface 4a. The wire bonding method is the same as that of Embodiment 1.

As described above, in the optical communication module according to Embodiment 3, the plurality of wires 7 are provided between the lead 2 and the metal pattern 5 formed on the sub-mount flat surface 4a, and the plurality of wires 7 are arranged on the top surface 2a of the one lead in a row along the direction parallel to the sub-mount flat surface 4a perpendicular to the top surface 2a of the one lead. Thus, the lengths of the wires can be made substantially equal to each other, thus providing an effect that an optical communication module having more excellent high-frequency characteristics can be obtained.

### Embodiment 4

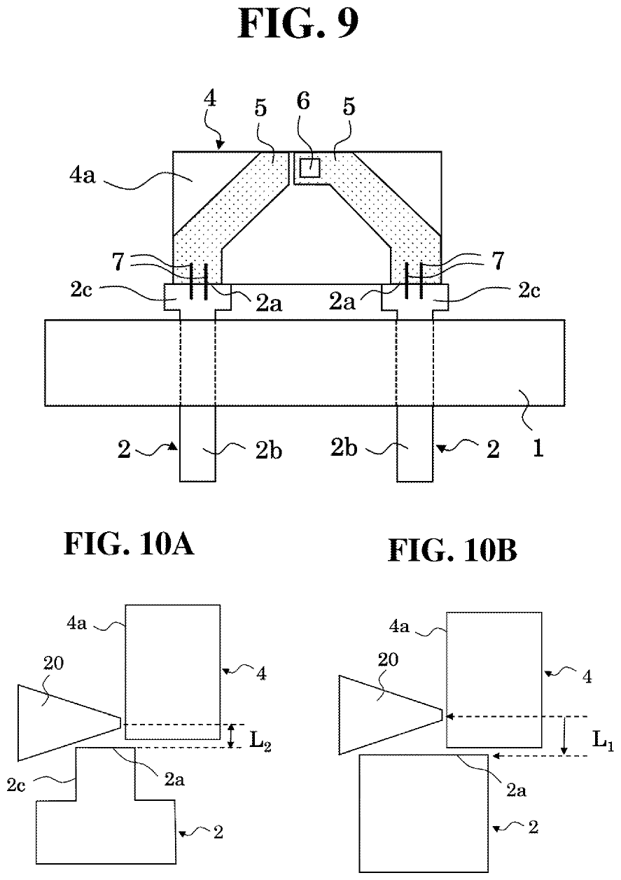

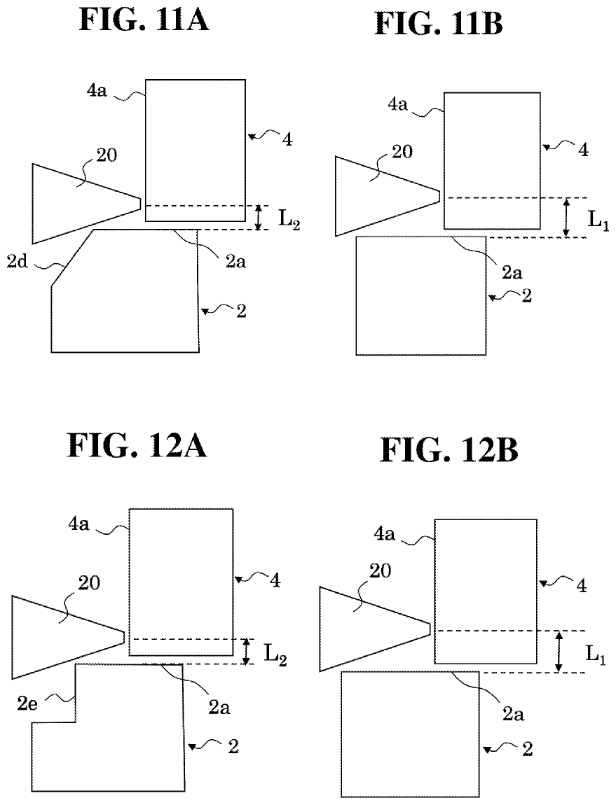

FIG. 9 is a schematic view showing a main part including the stem 1, the lead 2, and the sub-mount 4 in an optical communication module according to Embodiment 4. FIG. 10 is a schematic diagram showing a main part including the capillary 20, the lead 2, and the sub-mount 4 in the manufacturing method for the optical communication module according to Embodiment 4.

The tip end of the lead 2 in the optical communication module according to Embodiment 4 is provided with a T-shaped surface 2c which is parallel to the sub-mount flat surface 4a and T-shaped (FIG. 9). A cross section of a surface perpendicular to the sub-mount flat surface 4a is projecting-shaped (FIG. 10A). That is, a part of the side surface 2b of the tip end of the lead 2 forms the T-shaped surface 2c.

The wire 7 is bonded to the T-shaped surface 2c of the tip end of the lead 2. Since the width of the T-shaped surface 2c at the tip end of the lead 2 in the direction parallel to the sub-mount flat surface 4a is wider than the width of the cylindrical portion of the lead 2, a plurality of wires 7 can be easily provided on the T-shaped surface 2c. FIG. 9 shows an aspect in which two wires are bonded to the T-shaped surface 2c of the tip end of the lead 2.

In the optical communication module according to Embodiment 4, the plurality of wires 7 are provided on the T-shaped surface 2c of the tip end of the lead 2, thus providing an effect that an optical communication module capable of realizing more excellent high-frequency characteristics can be obtained as compared with the case where connection is made by one wire 7.

A method for manufacturing an optical communication module according to Embodiment 4 will be described below.

First, the tip end of the lead 2 is rolled in a direction perpendicular to the sub-mount flat surface 4a. As a result, the tip end of the lead 2 is processed into a T-shape in a direction parallel to the sub-mount flat surface 4a and into a projecting shape in a direction perpendicular to the sub-mount flat surface 4a, so that the T-shaped surface 2c as shown in FIG. 9 is formed.

By wire bonding, the capillary 20 is lowered to the sub-mount flat surface 4a, and the metal ball 7a formed at one end of the wire 7 is pressed against the metal pattern 5 (not shown) formed on the sub-mount flat surface 4a and bonded thereto by thermocompression bonding.

After bonding the metal ball 7a which is one end of the wire 7, the capillary 20 is raised and further moved to a position above the T-shaped surface 2c provided at the tip end of the lead 2. The capillary 20 is lowered from the upper position to the T-shaped surface 2c, and the other end of the wire 7 is bonded to the T-shaped surface 2c of the tip end of the lead 2. FIG. 10A schematically shows a state in which the capillary 20 is lowered to approach the sub-mount flat surface 4a.

Noted that the conductive member for connection 10 may be formed on the T-shaped surface 2c, and the other end of the wire 7 may be bonded to the lead 2 through bonding to the conductive member for connection 10. In this case, the bonding strength of the wire 7 is further increased.

The features of the method for manufacturing an optical communication module according to Embodiment 4 will be described with reference to a comparative example in the FIG. 10B. In the optical communication module according to the comparative example, the tip end of the lead 2 is not rolled at all. That is, the lead 2 has a general cylindrical shape.

FIG. 10B shows a state in which the capillary 20 is lowered until the capillary 20 comes close to the metal pattern 5 formed on the sub-mount flat surface 4a in the case where the tip end of the lead 2 is not rolled at all as in the comparative example.

In the comparative example shown in FIG. 10B, even if a position where the wire 7 is formed on the sub-mount flat surface 4a is set as close as possible to the side of the top surface 2a of the lead 2, since the capillary 20 is taper shaped, there is a restriction on the distance to the position where the tapered surface forming the side surface of the capillary 20 is not in contact with the tip end of the lead 2. That is, the position at which the capillary 20 can be lowered to the sub-mount flat surface 4a is restricted by the shape of the lead 2, and as shown in FIG. 10B, the distance L₁ between the central axis of the capillary 20 and the lead surface 2a of the lead 2 is a limit.

On the other hand, according to the manufacturing method for the optical communication module of Embodiment 4, since the T-shaped surface 2c is formed at the tip end of the lead 2 which has a projecting-shaped cross section in the direction perpendicular to the T-shaped surface 2c as shown in FIG. 10A, the position where the tapered surface forming the side surface of the capillary 20 is not in contact with the projecting-shaped tip end of the lead 2 is closer to the sub-mount flat surface 4a than in the comparative example as shown in FIG. 10B.

That is, if the position of the capillary 20 is the same as that in the comparative example, the capillary 20 can be lowered more deeply toward the sub-mount flat surface 4a. This is because the capillary 20 can be lowered until the tapered surface of the capillary 20 comes into contact with the projecting-shaped corner portion of the tip end of the lead 2.

Consequently, the distance L₂ between the lowerable position of the capillary 20 shown in FIG. 10A and the top surface 2a of the lead 2 can be made shorter than the distance L₁ of the comparative example. Since the distance L₂ is shorter than the distance L₁ in the comparative example, the wire length of the wire 7 between the lead 2 and the metal pattern 5 formed on the sub-mount flat surface 4a is also shorter than that in the comparative example. That is, in the method for manufacturing an optical communication module according to Embodiment 4, the wire length can be further shortened.

In addition, in the wire bonding method according to the present embodiment, for example, since the rotation operation of the stem 1 at the time of wire bonding which is necessary in the manufacturing method for the optical communication module according to Embodiment 1 becomes unnecessary, the working time required for the wire bonding step is shortened, thus providing also an effect of improving the productivity.

As described above, in the optical communication module and the method for manufacturing the same according to Embodiment 4, the tip end of the lead 2 is rolled into the T-shaped surface 2c in the direction parallel to the sub-mount flat surface 4a and into the projecting shape in the direction perpendicular to the sub-mount flat surface 4a. Consequently, the wire length of the wire 7 can be easily shortened, thus providing an effect that an optical communication module capable of realizing better high-frequency characteristics and a method for manufacturing the same are obtained.

### Embodiment 5

FIG. 11A is a schematic diagram showing a main part including the capillary 20, the leads 2, and the sub-mount 4 in the structure of the optical communication module and the method for manufacturing the same according to Embodiment 5. Noted that FIG. 11B shows a comparative example.

In the optical communication module according to Embodiment 5, a tapered surface 2d is partially provided at the corner portion of the tip end of the lead 2 on the side where the capillary 20 is lowered at the time of wire bonding. That is, a part of the side surface 2b of the tip end of the lead 2 forms the tapered surface 2d.

A method for manufacturing an optical communication module according to Embodiment 5 will be described below.

First, the tapered surface 2d is formed at the corner portion of the tip end of the lead 2 on the side where the capillary 20 is lowered at the time of the wire bonding. As an example of a method of forming the tapered surface 2d, formation by machining can be given.

By the wire bonding, the capillary 20 is lowered to the sub-mount flat surface 4a, and the metal ball 7a (not shown) formed at one end of the wire 7 is pressed against the metal pattern 5 (not shown) formed on the sub-mount flat surface 4a and bonded thereto by thermocompression bonding. FIG. 11A schematically shows a state in which the capillary 20 is lowered to approach the sub-mount flat surface 4a.

After bonding the metal ball 7a, the stem 1 is rotated to a position where the tapered surface 2d of the lead 2 becomes perpendicular to the vertical moving direction of the capillary 20. Next, the capillary 20 is moved to a position directly above the tapered surface 2d of the lead 2 and is lowered toward the tapered surface 2d of the lead 2 so that the other end of the wire 7 is bonded to the tapered surface 2d of the lead 2.

Noted that the conductive member for connection 10 may be formed on the tapered surface 2d, and the other end of the wire 7 may be bonded to the lead 2 through bonding to the conductive member for connection 10. In this case, the bonding strength of the wire 7 is further increased.

The features of the method for manufacturing an optical communication module according to Embodiment 5 will be described with reference to the comparative example in FIG. 11B. Since the comparative example shown in FIG. 11B is the same as FIG. 10B in the description of Embodiment 4, the description of the comparative example is omitted.

According to the method for manufacturing an optical communication module of Embodiment 5, since the tapered surface 2d is formed at the tip end of the lead 2 which has a tapered cross section in the direction perpendicular to the tapered surface 2d as shown in FIG. 11A, the capillary 20 can be lowered more deeply toward the sub-mount 4 than in the comparative example shown in FIG. 11B when the position of the capillary 20 in the upper side with respect to the sub-mount flat surface 4a is the same. This is because the tapered surface, which is the side surface of the capillary 20, can be lowered until it comes into contact with the tapered surface 2d of the lead 2.

Consequently, the distance L₂ between the position where the capillary 20 can be lowered and the top surface 2a of the lead shown in FIG. 11A can be made shorter than the distance L₁ in the comparative example. Since the distance L₂ is shorter than the distance L₁ in the comparative example, the wire length of the wire 7 between the lead 2 and the metal pattern 5 formed on the sub-mount flat surface 4a is also shorter in the optical communication module according to Embodiment 5 than in the comparative example.

In the wire bonding method according to Embodiment 5, rotation operation of the stem 1 can be completed at a rotation angle smaller than the rotation angle corresponding to the taper angle θₜ of the capillary 20 in the rotation operation of the stem 1 at the time of the wire bonding, which is required in the method for manufacturing an optical communication module according to Embodiment 1, by the angle at which the tapered surface 2d of the lead 2 is inclined with respect to the side surface 2b of the lead. Consequently, since the operation time required for the wire bonding step is shorter than that in the method for manufacturing an optical communication module according to Embodiment 1, the productivity is also improved.

As described above, in the optical communication module and the method for manufacturing the same according to Embodiment 5, since the tapered surface 2d is provided at the tip end of the lead 2, the wire length of the wire 7 can be easily shortened, thus providing an effect that an optical communication module capable of realizing better high-frequency characteristics and a method for manufacturing the same are obtained.

### Embodiment 6

FIG. 12A is a schematic diagram showing a main part including the capillary 20, the lead 2 and the sub-mount 4 in the structure of an optical communication module and the method for manufacturing the same according to Embodiment 6. Noted that FIG. 12B is a comparative example.

In the optical communication module according to Embodiment 6, a stepped surface 2e is provided at the corner portion of the tip end of the lead 2 on the side where the capillary 20 is lowered at the time of wire bonding. The stepped surface 2e of the lead 2 and the sub-mount flat surface 4a are parallel to each other. That is, a part of the side surface 2b of the tip end of the lead 2 forms the stepped surface 2e.

A method for manufacturing an optical communication module according to Embodiment 6 will be described below.

First, the stepped surface 2e is formed at the corner portion of the tip end of the lead 2 on the side where the capillary 20 is lowered at the time of the wire bonding. As an example of a method for forming such the stepped surface 2e, formation by machining can be given.

By the wire bonding, the capillary 20 is lowered to the sub-mount flat surface 4a, and the metal ball 7a (not shown) formed at one end of the wire 7 is pressed against the metal pattern 5 (not shown) formed on the sub-mount flat surface 4a and bonded thereto by thermocompression bonding. FIG. 12A schematically shows a state in which the capillary 20 is lowered to approach the sub-mount flat surface 4a.

Next, the capillary 20 is moved to a position directly above the stepped surface 2e of the lead 2 and is lowered toward the stepped surface 2e of the lead 2 so that the other end of the wire 7 is bonded to the stepped surface 2e of the lead 2. A plurality of wires 7 may be formed.

Noted that the conductive member for connection 10 may be formed on the stepped surface 2e, and the other end of the wire 7 may be bonded to the lead 2 through bonding to the conductive member for connection 10. In this case, the bonding strength of the wire 7 is further increased.

The features of the method for manufacturing an optical communication module according to Embodiment 6 will be described with reference to a comparative example in FIG. 12B. Noted that since the comparative example shown in FIG. 12B is the same as FIG. 10B in the description of Embodiment 4, the description of the comparative example is omitted.

According to the method for manufacturing an optical communication module of Embodiment 6, since the stepped surface 2e is formed at the tip end of the lead 2 which has a partially cut stepped shape in the direction perpendicular to the stepped surface 2e as shown in FIG. 12A, when the position of the capillary 20 in the upper side with respect to the sub-mount flat surface 4a is the same, the capillary 20 can be lowered more deeply toward the sub-mount 4 than in the comparative example shown in FIG. 12B. This is because the tapered surface of the capillary 20 can be lowered until it comes into contact with the corner portion of the stepped surface 2e of the lead 2.

Consequently, the distance L₂ between the position where the capillary 20 can be lowered and the top surface 2a of the lead shown in FIG. 12A can be made shorter than the distance L₁ in the comparative example. Since the distance L₁ is shorter than the distance L₂ in the comparative example, in the optical communication module according to Embodiment 6, the wire length of the wire 7 between the lead 2 and the metal pattern 5 formed on the sub-mount flat surface 4a is shortened as compared with the comparative example.

In addition, in the wire bonding method according to Embodiment 6, since the rotation operation of the stem 1 at the time of the wire bonding, which is necessary in the manufacturing method for the optical communication module according to Embodiment 1, for example, becomes unnecessary, the working time required for the wire bonding step is shortened, thus providing an effect that the productivity is also improved.

As described above, in the optical communication module and the method for manufacturing the same according to Embodiment 6, since the stepped surface 2e is provided at the tip end of the lead 2, the wire length of the wire 7 can be easily shortened, thus providing an effect that an optical communication module capable of realizing better high-frequency characteristics and a method for manufacturing the same are obtained.

### Embodiment 7

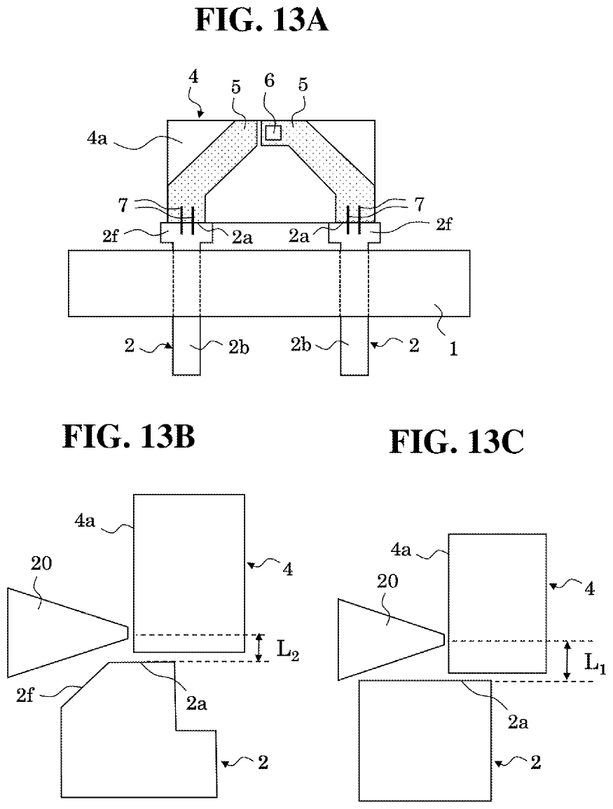

FIG. 13A is a schematic view showing a main part including the stem 1, the lead 2 and the sub-mount 4 in the optical communication module according to Embodiment 7. FIG. 13B is a schematic diagram showing a main part including the capillary 20, the lead 2 and the sub-mount 4 in the manufacturing method for the optical communication module according to Embodiment 7. FIG. 13C shows a comparative example.

The tip end of the lead 2 in the optical communication module according to Embodiment 7 has a T-shape in a direction parallel to the sub-mount flat surface 4a (FIG. 13A), and has a tapered surface in a vertical cross section on the side where the capillary 20 moves up and down (FIG. 13B). Hereinafter, this surface is referred to as a T-shaped tapered surface 2f. That is, a part of the side surface 2b of the tip end of the lead 2 forms the T-shaped tapered surface 2f. On the other hand, a surface opposite to the T-shaped tapered surface 2f has a stepped shape.

The wire 7 is bonded to the T-shaped tapered surface 2f of the lead 2. Since the T-shaped tapered surface 2f of the lead 2 is wider than the cylindrical portion of the lead 2, a plurality of wires 7 can be easily provided. In FIG. 13A, two wires are bonded to the T-shaped tapered surface 2f of the lead 2.

In the optical communication module according to Embodiment 7, the plurality of wires 7 can be easily provided on the T-shaped tapered surface 2f of the lead 2, thus providing an effect of obtaining an optical communication module which can realize more excellent high-frequency characteristics than the case of connection by a single wire 7.

A method for manufacturing an optical communication module according to Embodiment 7 will be described below.

First, the tip end of the lead 2 is rolled. By this rolling process, the stepped shape is formed in a part of the tip end of the lead 2, and the tip end of the lead 2 becomes the T-shape in a direction parallel to the sub-mount flat surface 4a. The T-shaped tapered surface 2f is formed at the tip end of the lead 2 by cutting a part of a portion where the wire bonding is scheduled on the side opposite to the surface where the stepped shape is formed.

Consequently, the surface of the tip end of the lead 2 on the side where the capillary 20 moves up and down has the tapered shape when viewed in the cross-sectional direction and the T-shape when viewed in the direction perpendicular to the sub-mount flat surface 4a.

By the wire bonding, the capillary 20 is lowered to the sub-mount flat surface 4a, and the metal ball 7a (not shown) formed at one end of the wire 7 is pressed against the metal pattern 5 (not shown) formed on the sub-mount flat surface 4a and bonded thereto by thermocompression bonding.

After the metal ball 7a is bonded, the stem 1 is rotated to a position where the T-shaped tapered surface 2f at the tip end of the lead 2 is perpendicular to the vertical moving direction of the capillary 20. The capillary 20 is moved to a position above the T-shaped tapered surface 2f of the lead 2, the capillary 20 is lowered to the T-shaped tapered surface 2f of the lead 2, and the other end of the wire 7 is bonded to the T-shaped tapered surface 2f of the lead 2. FIG. 13B schematically shows a state in which the capillary 20 is lowered to approach the sub-mount flat surface 4a.

Noted that the conductive member for connection 10 may be formed on the T-shaped tapered surface 2f, and the other end of the wire 7 may be bonded to the lead 2 through bonding to the conductive member for connection 10. In this case, the bonding strength of the wire 7 is further increased.

Features of the method for manufacturing an optical communication module according to Embodiment 7 will be described. Since the comparative example shown in FIG. 13C is the same as FIG. 10B in the description of Embodiment 4, the description of the comparative example is omitted.

According to the method for manufacturing an optical communication module of Embodiment 7, since the T-shaped tapered surface 2f is formed at the tip end of the lead 2 which has a tapered cross section in a direction perpendicular to the T-shaped tapered surface 2f as shown in FIG. 13B, the capillary 20 can be lowered more deeply toward the sub-mount 4 than in the comparative example shown in FIG. 13C when the position of the capillary 20 in the upper side with respect to the sub-mount flat surface 4a is the same. This is because the tapered surface which is the side surface of the capillary 20 can be lowered until it comes into contact with the T-shaped tapered surface 2f of the lead 2.

Consequently, the distance L₂ between the position where the capillary 20 can be lowered and the top surface 2a of the lead shown in FIG. 13B can be made shorter than the distance L₁ in the comparative example. Since the distance L₂ is shorter than the distance L₁ in the comparative example, the wire length of the wire 7 between the lead 2 and the metal pattern 5 formed on the sub-mount flat surface 4a is also shorter in the optical communication module according to Embodiment 7 than in the comparative example.

In addition, in the wire bonding method according to Embodiment 7, the rotation of the stem 1 can be completed at a rotation angle smaller than the rotation angle in the rotation operation of the stem 1 at the time of the wire bonding, which is required in the manufacturing method for the optical communication module according to Embodiment 1, for example, by the angle by which the T-shaped tapered surface 2f of the lead 2 is inclined with respect to the side surface 2b of the lead. Consequently, the working time required for the wire bonding step is shortened, thus providing an effect that the productivity is also improved.

As described above, in the optical communication module and the method for manufacturing the same according to Embodiment 7, since the T-shaped tapered surface 2f is provided at the tip end of the lead 2, the plurality of wires 7 can be easily formed on one lead 2, and the wire length of the wires 7 can be easily shortened, thus providing an effect of obtaining an optical communication module capable of realizing better high-frequency characteristics and a method for manufacturing the same.

### Embodiment 8

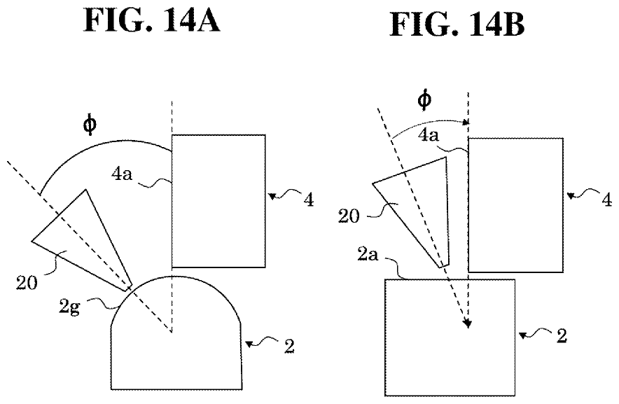

FIG. 14A is a schematic diagram showing a main part including the capillary 20, the lead 2, and the sub-mount 4 in the structure of the optical communication module and the method for manufacturing the same according to Embodiment 8. Noted that FIG. 14B shows a comparative example.

In the optical communication module according to Embodiment 8, the tip end of the lead 2 has a spherical surface 2g. That is, the top surface 2a of the lead 2 forms the hemispherical spherical surface 2g.

The method for manufacturing an optical communication module according to Embodiment 8 will be described below.

First, the tip end of the lead 2 is processed into a hemispherical shape to form the spherical surface 2g. An example of a method for forming such the spherical surface 2g is formation by cutting.

By wire bonding, the capillary 20 is lowered to the sub-mount flat surface 4a, and the metal ball 7a formed at one end of the wire 7 is pressed against the metal pattern 5 (not shown) formed on the sub-mount flat surface 4a and bonded thereto by thermocompression bonding.

The inclination angle of the stem 1 is adjusted so that the vertical moving direction of the capillary 20 is perpendicular to a position at a predetermined angle (hereinafter referred to as a wire bonding angle ϕ) from the extending direction of the lead 2 above the spherical surface 2g of the tip end of the lead 2. Assuming that the extending direction of the lead 2 is 0° and the angle perpendicular to the sub-mount flat surface 4a is 90°, the wire bonding angle ϕ can be arbitrarily set in the range of 0°<ϕ<90°.

The stem 1 is rotated such that the capillary 20 is positioned at the wire bonding angle ϕ with respect to the extending direction of the lead 2. Then the capillary 20 is lowered toward the spherical surface 2g of the lead 2, and the other end of the wire 7 is bonded to the spherical surface 2g of the lead 2.

Noted that the conductive member for connection 10 may be formed on the spherical surface 2g, and the other end of the wire 7 may be bonded to the lead 2 through bonding to the conductive member for connection 10. In this case, the bonding strength of the wire 7 is further increased.

The features of the method for manufacturing an optical communication module according to Embodiment 8 will be described with reference to a comparative example in FIG. 14B.

When the spherical surface 2g is not provided at the tip end of the lead 2, that is, when the top surface 2a of the lead is a flat surface, a state in which the capillary 20 is to be bonded to the top surface 2a of the lead at the wire bonding angle ϕ is shown in FIG. 14B. In the comparative example, even if an attempt is made to form the wire 7 on the top surface 2a of the lead, the wire 7 cannot be bonded to the top surface 2a of the lead with strong bonding strength because the wire bonding is performed from a direction inclined with the wire bonding angle ϕ. Consequently, even if the wire length of the wire 7 is shortened in order to improve the high-frequency characteristics, the bonding strength is a limitation.

On the other hand, according to the manufacturing method for the optical communication module of Embodiment 8, as shown in FIG. 14A, since the tip end of the lead 2 has the spherical surface 2g, when the wire bonding angle ϕ is in the range of 0<ϕ<90°, the capillary 20 is lowered from the vertical direction to the spherical surface 2g of the tip end of the lead 2 to bond the wire 7, so that the wire 7 having strong bonding strength can be formed.

Consequently, according to the wire bonding method of Embodiment 8, as compared with the comparative example shown in FIG. 14B, it is possible to realize wire bonding with a stronger bonding strength suitable for shortening the wire length, so that by applying the shortened wire 7 in the optical communication module of Embodiment 8, an optical communication module having excellent high-frequency characteristics can be obtained.

In addition, in the wire bonding method according to Embodiment 8, since the tip end of the lead 2 forms the spherical surface 2g, the wire bonding angle ϕ for inclining the stem 1 with respect to the extending direction of the lead 2 can be arbitrarily selected in contrast to the rotation angle in the rotation operation of the stem 1 at the time of wire bonding which is required in the manufacturing method for the optical communication module according to Embodiment 1. Therefore, it is possible to complete the rotation operation of the stem 1 at a rotation angle smaller than the inclination angle ϕ required in the case of Embodiment 1, and thus the working time required for the wire bonding process is shortened, thus providing an effect that improving the productivity is also obtained.

As described above, in the optical communication module and the method for manufacturing the same according to Embodiment 8, since the spherical surface 2g is provided at the tip end of the lead 2, the wire length of the wire 7 can be easily shortened, thus providing an effect of obtaining an optical communication module and a method for manufacturing the same which can realize more excellent high-frequency characteristics.

### Embodiment 9

A method for manufacturing an optical communication module according to Embodiment 9 will be described below.

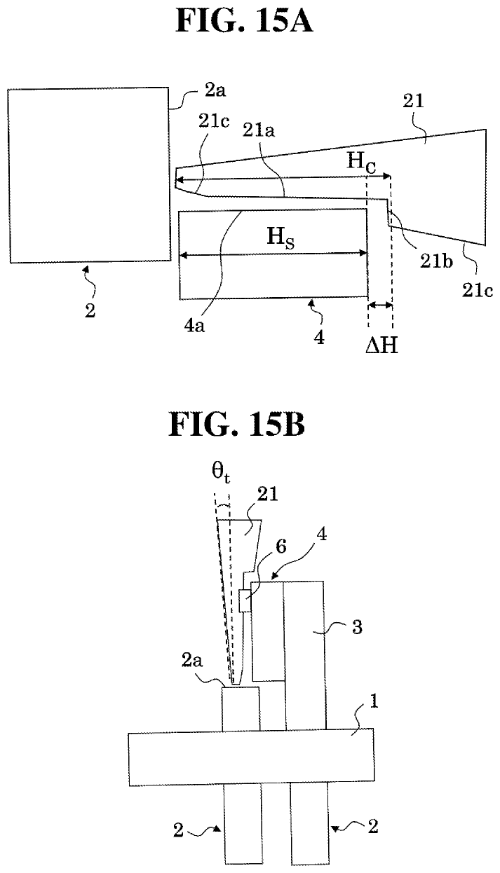

The method for manufacturing an optical communication module according to Embodiment 9 is characterized by a shape of the capillary of a wire bonding apparatus. FIG. 15A is a schematic diagram showing a shape of capillary 21 used in the method for manufacturing an optical communication module according to Embodiment 8.

As shown in FIG. 4, the capillary 20 used in the method for manufacturing an optical communication module according to Embodiment 1 has the structure in which the tip end of the capillary 20 expands so as to have the tapered shape at the constant taper angle θₜ when viewed from the cross section of the capillary 20. The capillary 20 is rotationally symmetric with respect to the central axis of the capillary 20.

The capillary 21 used in the method for manufacturing an optical communication module according to Embodiment 9, as shown in FIG. 15A, has a tapered portion 21c which is widened in a tapered shape from the tip end portion, and the flat portion 21a which is formed to be flat from one end in the middle of the tapered portion 21c. The capillary 21 further forms a stepped portion 21b on the other end side of the flat portion 21a and has a shape that returns from the corner of the stepped portion 21b to the original tapered portion 21c. Noted that the two tapered portions 21c separated by the flat portion 21a of the capillary 21 form one tapered surface.

The length H_{C} in the axial direction from the tip end of the capillary 21 to the stepped portion 21b is set to be longer by ΔH than the length Hs in the longitudinal direction of the sub-mount flat surface 4a of the sub-mount 4 of the optical communication module wire-bonded by the capillary 21.

The wire bonding step which is a characteristic step in the manufacturing method for the optical communication module according to Embodiment 9 will be described below.

In the wire bonding step, when the wire 7 is bonded to the lead surface 2a of the lead 2, the capillary 21 is lowered to the lead surface 2a of the lead in such a positional relationship that the flat portion 21a provided on the capillary 21 is opposed to the sub-mount flat surface 4a of the optical communication module, and the wire 7 is bonded to the lead 2. FIG. 15B schematically shows a state in which the capillary 21 is lowered until the capillary 21 comes close to the top surfaces 2a of the lead 2.

When wire bonding is performed using the capillary 21 having the above-described shape, as can be easily understood from FIG. 15B, the wire 7 can be provided closer to the sub-mount flat surface 4a side on the top surface 2a of the lead 2 by an amount corresponding to the substantial reduction in the radial width of the capillary 21 due to the formation of the flat portion 21a, as compared with the case of using general tapered capillaries.

As described above, in the method for manufacturing an optical communication module according to Embodiment 9, the flat portion 21a is provided on one side surface of the capillary 21, and wire bonding is performed on the top surface 2a of the lead 2 in such a positional relationship that the flat portion 21a of the capillary 21 is opposed to the sub-mount flat surface 4a of the sub-mount 4 of the optical communication module, thus providing an effect that an optical communication module capable of realizing better high-frequency characteristics and a method for manufacturing the same are obtained.

### Embodiment 10

A method for manufacturing an optical communication module according to Embodiment 10 will be described below.

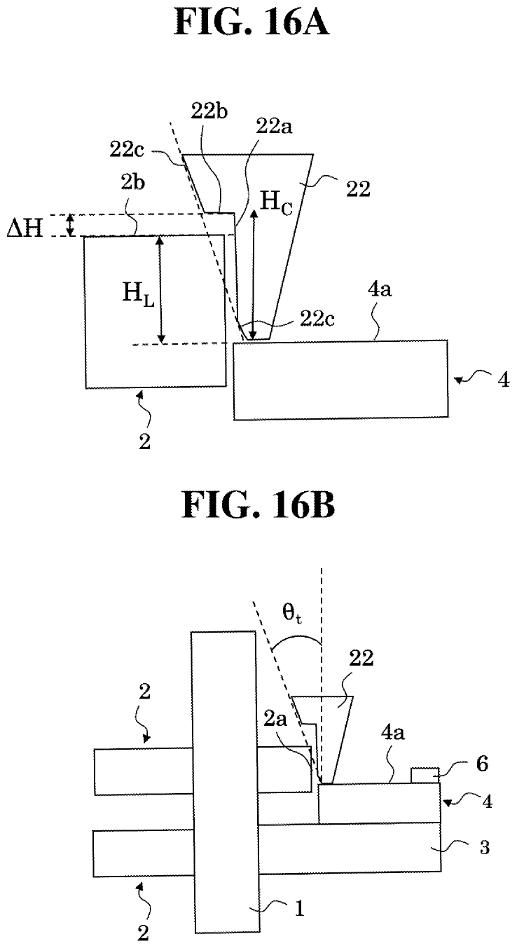

The method for manufacturing an optical communication module according to Embodiment 10 is characterized by the shape of the capillary of the wire bonding apparatus. FIG. 16A is a schematic diagram showing the shape of a capillary 22 used in the method for manufacturing an optical communication module according to Embodiment 10.

As shown in FIG. 4, the capillary 20 used in the method for manufacturing an optical communication module according to Embodiment 1 has the structure in which the capillary 20 expands from the tip end portion thereof at the constant taper angle θₜ so as to have the tapered cross section, and is rotationally symmetric with respect to the central axis of the capillary 20.

On the other hand, as shown in FIG. 16, the capillary 22 used in the method for manufacturing an optical communication module according to Embodiment 10 has a shape in which a tapered portion 22c is formed at a part of the side surface of the capillary 22 from the tip end, that is, in the middle of the tapered portion 22c, a flat portion 22a is formed flat from one end, and a stepped portion 22b is formed on the other end of the flat portion 22a, and the tapered portion 22c returns to the original tapered portion 22c from the corner of the stepped portion 22b. Noted that the length H_{C} in the axial direction from the tip end of the capillary 22 to the stepped portion 22b is set to be longer by ΔH than the distance HL in the radial direction of the lead 2 of the optical communication module wire-bonded by the capillary 22 from the position intersecting the sub-mount flat surface 4a to the side surface 2b of the lead.

The wire bonding step which is a characteristic step in the manufacturing method for an optical communication module according to Embodiment 10 will be described below.

In the wire bonding step, when the wire 7 is bonded to the metal pattern 5 formed on the sub-mount flat surface 4a, the capillary 22 is lowered to the sub-mount flat surface 4a of the lead 2 in such a positional relationship that the flat portion 22a provided on the capillary 22 is opposed to the top surface 2a of the lead of the optical communication module, and the wire 7 is bonded to the metal pattern 5. FIG. 16B schematically shows a state in which the capillary 22 is lowered until the capillary 22 comes close to the metal pattern 5 formed on the sub-mount flat surface 4a.

When wire bonding is performed using the capillary 22 having the above-described shape, as can be easily understood from FIG. 16B, the wire 7 can be provided closer to the lead 2 on the sub-mount flat surface 4a by an amount corresponding to the substantial reduction in the radial width of the capillary 22 by the flat portion 22a provided in the capillary 22 as compared with the case of using general tapered capillaries.

As described above, in the method for manufacturing an optical communication module according to Embodiment 10, the flat portion 22a is provided on one side surface of the capillary 22 and in the wire bonding, the wire 7 is bonded to the metal pattern 5 formed on the sub-mount flat surface 4a in such a positional relationship that the flat portion 22a provided on the capillary 22 is opposed to the top surface 2a of the lead, and thus the wire length of the wire 7 can be easily shortened, thus providing an effect that an optical communication module capable of realizing better high-frequency characteristics and a method for manufacturing the same are obtained.

### Embodiment 11

A method for manufacturing an optical communication module according to Embodiment 11 will be described below.

In the manufacturing method for the optical communication module according to Embodiment 11, the shape of the capillary of the wire bonding apparatus is the same as that of Embodiment 10, but the conductive member for connection 10 is formed on the side surface 2b of the lead, and a plurality of wires 7 are bonded to one conductive member for connection 10, that is, it is characterized in that the plurality of wires 7 are provided for one lead 2.

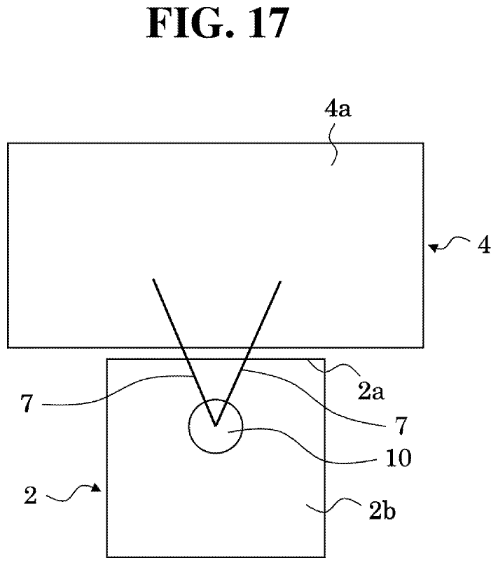

FIG. 17 is a schematic diagram showing the lead 2, the sub-mount 4, and the wires 7 electrically connecting the lead 2 and the sub-mount 4 according to the optical communication module according to Embodiment 11.

The wire bonding step which is a characteristic step in the manufacturing method for the optical communication module according to Embodiment 11 will be described below.

In the wire bonding step, when one end of the wire 7 is pressed against the metal pattern 5 (not shown) formed on the sub-mount flat surface 4a and bonded thereto by thermocompression bonding, the capillary 22 is lowered to the sub-mount flat surface 22a to bond the wire 7 to the metal pattern 5 in such a positional relationship that the flat portions 22a of the capillary 22 is opposed to the top surface 2a of the lead 2 on the optical communication module side.

The other end of the wire 7 is stitch-bonded to the conductive member for connection 10 formed on the side surface 2b of the lead, so that the wire 7 is bonded to the side surface 2b of the lead through bonding to the conductive member for connection 10. By performing the wire bonding on the conductive member for connection 10 multiple times, it is possible to easily manufacture an optical communication module in which the plurality of wires 7 are bonded to one conductive member for connection 10 as shown in FIG. 17.

As described above, in the method for manufacturing an optical communication module according to Embodiment 11, the flat portion 22a is provided on one side surface of the capillary 22 and in the wire bonding, the wire 7 is bonded to the metal pattern 5 formed on the sub-mount flat surface 4a in such a positional relationship that the flat portion 22a provided on the capillary 22 is opposed to the top surface 2a of the lead, and the other end of the wire 7 is wire-bonded to the conductive member for connection 10 formed on the side surface 2b of the lead, and such the wire-bonding is repeated to provide the plurality of wires 7 on the side surface 2b of the lead, thus providing an effect that an optical communication module capable of realizing better high-frequency characteristics and a method for manufacturing the same are obtained.

### Embodiment 12

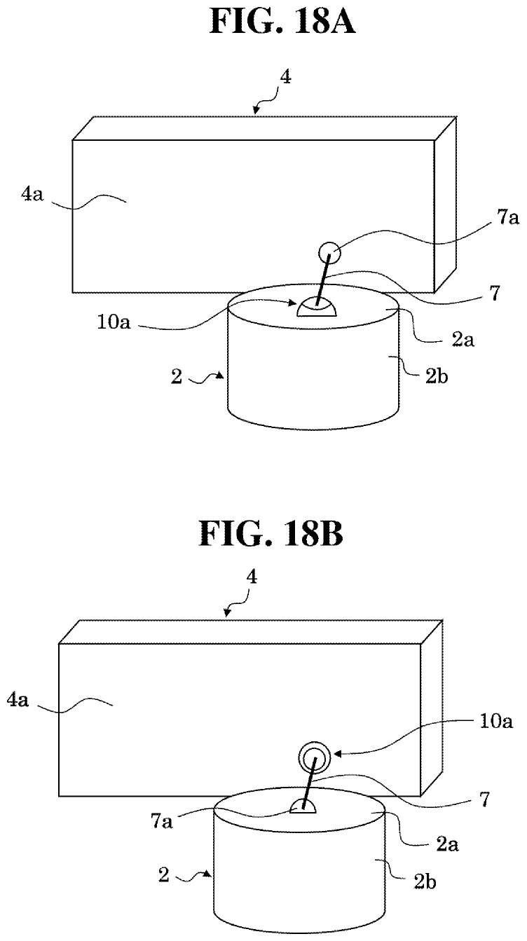

FIG. 18 is an enlarged schematic view of a main part including the wire 7 and the conductive member for connection 10a of an optical communication module according to Embodiment 12.

In the optical communication module according to Embodiment 1 or Modification 1 of Embodiment 1, the bump as an example of the conductive member for connection 10 is formed on the lead 2 side, then the lead 2 and the metal pattern 5 formed on the sub-mount flat surface 4a are connected with the wire 7 (FIG. 3), or the bump as an example of the conductive member for connection 10 is formed on the metal pattern 5 (not shown) formed on the sub-mount flat surface 4a, then the lead 2 and the metal pattern 5 formed on the sub-mount flat surface 4a are connected with the wire 7 (FIG. 5).

In the optical communication module and the method for manufacturing the same according to Embodiment 12, a double bump as an example of the conductive member for connection 10a different from the conductive member for connection 10 is formed on the lead 2 side of the optical communication module, then the lead 2 and the metal pattern 5 formed on the sub-mount flat surface 4a are connected with the wire 7 (FIG. 18A), or the double bump as an example of the conductive member for connection 10a is formed on the metal pattern 5 (not shown) formed on the sub-mount flat surface 4a, and the lead 2 and the metal pattern 5 formed on the sub-mount flat surface 4a are connected with the wire 7 (FIG. 18B).

The double bump which is the example of the conductive member 10a for connection indicates, for example, a bump structure in which a second bump is further provided on a first bump which is initially provided. Noted that when the second bump is provided, the first bump has a shape that is crushed by the second bump provided on the first bump. That is, the double bump is formed by two stacked bumps.

A method for manufacturing the double bump which is an example of the above-described conductive member 10a for connection will be described below.

Although the following description relates to a manufacturing method in which the double bump as the example of the conductive member for connection 10a is formed on the top surface 2a of the lead shown in FIG. 18A, the structure shown in FIG. 18B is also manufactured by a similar method.

A metal ball 7a is formed at the tip end of a wire material by dropping the wire material from a tip end of the capillary 20 above the top surface 2a of the lead of an optical communication module and melting the tip end of the wire material by electric discharge from a torch electrode. The capillary 20 is lowered to the side of the top surface 2a of the lead, and the metal ball 7a is pressed against the top surface 2a of the lead by thermocompression bonding, then the capillary 20 is raised while leaving the first metal ball 7a on the top surface 2a of the lead, and the remaining wire material is cut off so as to leave only the first metal ball 7a in a clamped state of the wire material. Through the above steps, the first bump is formed.

The second metal ball 7a is formed again at the tip end of the wire in the manner described above. The capillary 20 is lowered just above the first metal ball 7a formed on the top surface 2a of the lead and the second metal ball 7a is pressed against the first metal ball 7a by thermocompression bonding, then the capillary 20 is raised while leaving the second metal ball 7a on the top surface 2a of the lead, and the remaining wire material is cut while leaving the second metal ball 7a in a clamped state of the wire material.

Through the above steps, the double bump which is the example of the conductive member 10a for connection is formed.

As described above, the double bump is formed of two stacked bumps each formed of the metal ball 7a. Noted that when the second metal ball 7a is thermocompression-bonded to the first metal ball 7a, the first metal ball 7a has a shape crushed by the applied force. An example of a metal constituting each bump is gold.

By providing the double bump, the bonding strength between the wire 7 and the double bump at the time of stitch bonding to the double bump is remarkably improved as compared with the case of a single bump used in the manufacturing method for the optical communication module according to Embodiment 1, for example. This is because the bonding strength between the second bump and the metal pattern 5 formed on the top surface 2a of the lead or the sub-mount flat surface 4a is increased by crushing the first bump of the double bump.

As described above, in the optical communication module according to Embodiment 12, since the conductive member for connection is formed by the double bump, even when the wire length of the wire 7 between the lead 2 and the metal pattern 5 formed on the sub-mount flat surface 4a is shortened, the wire 7 having a stronger bonding strength is provided, thus providing a remarkable effect that an optical communication module capable of realizing excellent high-frequency characteristics can be obtained.

Further, in the method for manufacturing an optical communication module according to Embodiment 12, since the conductive member for connection is formed by the double bump, it is possible to easily form the wire 7 having a further short wire length while maintaining a strong bonding strength, thus providing a remarkable effect that an optical communication module having excellent high-frequency characteristics can be easily obtained.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 stem
1a insulating member
2 lead
2a top surface of lead
2b side surface of lead
2c T-shaped surface
2d tapered surface
2e stepped surface
2f T-shaped tapered surface
2g spherical surface
3 heat sink block
4 sub-mount
4a sub-mount flat surface
5 metal pattern
6 semiconductor light emitting element
6a semiconductor light receiving element
7 wire
7a metal ball
10 conductive member for connection (bump)
10a conductive member for connection (double bump)
20, 21, 22 capillary
21a 22a flat portion
21b 22b stepped portion
21c 22c tapered portion
100 optical communication module

1. An optical communication module comprising:
a plate-shaped stem;
a plurality of leads penetrating through the stem via insulating members;
a conductive member for connection formed on either a top surface or a side surface of at least one lead among the plurality of leads;
a heat sink block provided on the stem;
a sub-mount which is fixed to the heat sink block and is provided with a metal pattern on a flat surface thereof;
a semiconductor light emitting element which is fixed to the metal pattern and emits laser light; and
a wire in which a metal ball formed at one end thereof is bonded to the metal pattern and the other end thereof is bonded to the at least one lead among the plurality of leads through bonding to the conductive member for connection, wherein
the top surface of the at least one lead among the plurality of leads has a spherical surface, and the conductive member for connection is provided on the spherical surface.

2. The optical communication module according to claim 1, wherein the conductive member for connection is a bump.

3. The optical communication module according to claim 1, wherein the conductive member for connection is a double bump in which two bumps are stacked.

4. (canceled)

5. The optical communication module according to claim 1, wherein a plurality of the wires are bonded to the at least one lead.

6.-16. (canceled)

17. A method for manufacturing an optical communication module comprising:
fixing a sub-mount having a metal pattern formed on a flat surface thereof to a heat sink block provided on a plate-shaped stem;
fixing a semiconductor light emitting element to the metal pattern;
bonding a metal ball formed at one end of a wire to the metal pattern in a state where a flat surface of the stem is inclined at an angle of 90°−θₜ with respect to a reference surface, the reference surface being a surface perpendicular to an axial direction of a capillary, the capillary having a tapered shape expanding at a taper angle θₜ from a tip end thereof and supporting the wire by a wire insertion hole provided along a central axis;
forming a conductive member for connection on a top surface or a side surface of at least one lead among a plurality of leads provided so as to penetrate through the stem; and
bonding the other end of the wire to the at least one lead through bonding to the conductive member for connection in a state in which the flat surface of the stem is inclined at the taper angle θₜ with respect to the reference surface.

18. The method for manufacturing an optical communication module according to claim 17, wherein
the conductive member for connection is a bump, the bump is formed on the side surface of the at least one lead of the plurality of leads, and the other ends of a plurality of the wires are connected to the bump.

19. A method for manufacturing an optical communication module comprising:
forming a conductive member for connection on a top surface of at least one lead among a plurality of leads penetrating through a plate-shaped stem;
fixing a sub-mount having a metal pattern formed on a flat surface thereof to a heat sink block provided on the stem;
fixing a semiconductor light emitting element to the metal pattern;
bonding a metal ball formed at one end of a wire to the metal pattern in a direction perpendicular to the metal pattern using a capillary having a tapered portion extending from a tip end of the capillary along a central axis, a flat portion having one end connected to the tapered portion, and a stepped portion connected to the other end of the flat portion, the capillary supporting the wire by a wire insertion hole provided along the central axis, a length from the tip end of the capillary to the stepped portion thereof being longer than a length of the sub-mount in the axial direction; and
rotating the stem until the flat portion of the capillary and the flat surface of the sub-mount are opposed to each other, and bonding the other end of the wire to a top surface or a side surface of the at least one lead among the plurality of leads provided so as to penetrate through the stem.

20. (canceled)

21. A method for manufacturing an optical communication module comprising:
fixing a sub-mount having a metal pattern formed on a flat surface thereof to a heat sink block provided on a plate-shaped stem;
fixing a semiconductor light emitting element to the metal pattern;
processing a top surface of a tip end of at least one lead among a plurality of leads penetrating through the stem into a hemispherical spherical surface;
forming a conductive member for connection on the spherical surface;
bonding a metal ball formed at one end of a wire to the metal pattern from a direction perpendicular to the metal pattern by using a capillary which supports the wire by a wire insertion hole provided along a central axis thereof and extends in a tapered shape from a tip end of the capillary along the central axis; and
rotating the stem until the conductive member for connection is positioned in a descending direction of the capillary, and bonding the other end of the wire to the at least one lead through bonding to the conductive member for connection.

22. The method for manufacturing an optical communication module according to claim 21, wherein
the wire is one of a plurality of wires.

23. The method for manufacturing an optical communication module according to claim 19, wherein
the conductive member for connection is a bump.

24. The method for manufacturing an optical communication module according to claim 19, wherein
the conductive member for connection is a double bump in which two bumps are stacked.

25. An optical communication module comprising:
a plate-shaped stem;
a plurality of leads penetrating through the stem via insulating members;
a conductive member for connection provided on a tapered surface, the tapered surface inclined toward the tip end of at least one lead among the plurality of leads being provided at the tip end thereof;
a heat sink block provided on the stem;
a sub-mount which is fixed to the heat sink block and is provided with a metal pattern on a flat surface thereof;
a semiconductor light emitting element which is fixed to the metal pattern and emits laser light; and
a wire in which a metal ball formed at one end thereof is bonded to the metal pattern and the other end thereof is bonded to the at least one lead among the plurality of leads through bonding to the conductive member for connection.
